(19) United States
(12) Patent Application Publication
(10) Pub. No.: US 2002/0089041 A1
(43) Pub. Date: Jul. 11, 2002

(54) Lead-frame design modification to facilitate removal of resist tape from the lead-frame

(76) Inventors: Michael L. Scherbarth, Tracy, CA (US); Gerald K. Fehr, La Selva Beach, CA (US)

Correspondence Address: CENTRAL COAST PATENT AGENCY, PO BOX 187, AROMAS, CA, 95004, US

(21) Appl. No.: 09/755,480

(22) Filed: Jan. 5, 2001

(51) Int. Cl. H01L 23/495

(52) U.S. Cl. 257/666; 438/123

(57) ABSTRACT

A lead frame apparatus for holding IC packages during IC package processing is provided. The lead frame apparatus comprises a substantially flat thin strip of conductive material having substantially parallel sides and square ends forming the lead frame apparatus, a strip of adhesive material adhered to one surface of lead frame apparatus, the overall dimensions of the strip substantially the same as the overall dimensions of the lead frame apparatus, a plurality of die-attach pads arranged on the non-adhesive surface of the lead frame apparatus, the pads for receiving IC packages for encapsulation by molding, and at least one geometric area of material alteration formed in the conductive material forming the lead frame, the area located substantially at either frame end, wherein a user accesses the strip of adhesive material through utilization of the material alteration for the purpose of removing the adhesive material from the surface of the lead frame.

### FIELD OF THE INVENTION

The present invention is in the area of integrated circuit (IC) manufacturing, and pertains in particular to apparatus and methods for modifying the narrow end or ends of a lead frame to facilitate successful tape removal during IC processing.

### BACKGROUND OF THE INVENTION

In general, the plastic encapsulation of ICs to form packaged ICs with electrical leads is as follows. Typically, ICs in die form are attached to mounting areas called islands, or die attach pads, on strips termed lead frames in the art. In this specification the die attach pad terminology will be used. The lead frames are typically made of a thin, flat, metal sheet chosen for a number of characteristics including electrical conductivity. Lead frames typically have multiple individual die attach pads, each for supporting an individual IC during a molding operation wherein the individual dies are encapsulated in plastic material, leaving electrical leads protruding from the plastic encapsulation.

In many cases, densely packaged ICs are manufactured to maximize connectivity by utilizing all four sides of the chip. Around the perimeter of each die attach pad a typical lead frame has a pattern of individual conductive leads extending toward, but not contacting, the die attach pad. The die attach pads and individual leads are formed by selective removal of material in the lead frame, such as by stamping. The number of the leads at a frame with a single die attach pad depends directly on the configuration of the particular IC die to be mounted, that is, the number and location of electrical terminations to the die.

A plastic package with external leads for connecting to, for example, a printed circuit board, is typically formed by an encapsulation process. Mating molds are placed on each side of the lead frame and liquid-phase polymer is injected to encapsulate IC dies attached to the die attach pads in each frame. The lead frame is designed to dam the flow of liquid-phase polymer as the polymer moves to the outer edges of each individual mold, stopping at the points where each mold contacts surfaces of the lead frame. To stop the flow of liquid-phase polymer between leads, the lead frame has a pattern of dam bars between individual leads, so a contiguous band of material is formed around the periphery of the island. This contiguous band prevents the polymer from flooding the entire lead frame, and also allows the lead frame to be one contiguous piece of material until subsequent trimming operations are performed.

After the polymer material solidifies and the molds are removed, a following operation in the manufacturing process removes the excess plastic in the region around the mold outline and the dam bars. This is termed de-junking in the art. A de-damming process then removes the dam bar between each lead, providing electrical isolation integrity for each lead. De-damming is a process of removing all or part of each dam bar by use of a punch with a pattern of teeth conforming to the pattern of the dam bars in the lead frame. Often, the de-damming and de-junking can be done in a single step.

In state-of-the-art manufacturing automated machines are used to perform the encapsulation process. Automated machines are marketed by a number of manufacturers, including several Japanese manufacturers, and include molds made to close over one or more lead frames, as described above, wherein after an encapsulation material is injected and caused to solidify. The encapsulation material is typically a liquid-phase polymer material.

Lead frame based chip-scale-packaging (CSP) is currently gaining wide popularity in the IC-packaging industry. CSP describes a package that dimensionally is no more than 1.2 times the length and width of the die the package is attached to. In order to control mold flash and/or resin bleed at the underside of a lead frame, a high thermal-resist tape is used on the lead frame during molding. In typical art, lead frames are provided with tape attached thereto and covering one side of the frame, the tape cut to the edges of the frame. In some cases manufacturers provide the tape and apply it to already-purchased lead frames. Although pre-taped lead frames are available, little information is available in the industry regarding how to remove the tape during processing.

In current art, IC packaging houses remove the tape by hand. This requires great skill and care to prevent damage. Some examples of damage that may occur during hand removal of resist tape include bending damage to lead frame, mold cracking, die cracking, and delaminating. Another problem associated with tape removal is a tendency for the tape to be torn off into smaller pieces during the process.

Some packaging houses apply heat to a lead frame in order to facilitate removal of the tape in one piece. However, the greatest challenge is how to physically get access to and begin separating the tape from the lead frame.

What is clearly needed is a method that enables simple physical access to the edge of the thermal-resist tape applied to a lead frame. Such a method will enable easy and secure access to the tape in order to enable safe separation of the tape from the lead frame.

### SUMMARY OF THE INVENTION

In a preferred embodiment of the present invention, a lead frame apparatus for holding IC packages during IC package processing is provided. The lead frame apparatus comprises, a substantially flat thin strip of conductive material having substantially parallel sides and square ends forming the lead frame apparatus, a strip of adhesive material adhered to one surface of lead frame apparatus, the overall dimensions of the strip substantially the same as the overall dimensions of the lead frame apparatus, a plurality of die-attach pads arranged on the non-adhesive surface of the lead frame apparatus, the pads for receiving IC packages for encapsulation by molding and at least one geometric area of material alteration formed in the conductive material forming the lead frame, the area located substantially at either or in some cases both frame ends. A user accesses the strip of adhesive material through utilization of the material alteration for the purpose of removing the adhesive material from the surface of the lead frame.

In a preferred aspect, the adhesive material is thermal resist tape. In this aspect, the thermal resist tape, after application to the frame, is dimensionally equal to the overall dimensions of the frame. In one aspect, the material alteration is a perforated tab wherein the geometric area defining the material alteration is rectangular. In some cases, the material alteration spans the entire width of the lead frame. Also in some cases, etching before application of the adhesive material produces the material alteration. In some aspects, the material alteration is characterized by an absence of material. In these aspects, a material removal process performed before application of the adhesive material produces the material alteration. In one aspect, the geometric area defining the material alteration is rectangular. In another aspect, the geometric area defining the material alteration is annular. In some aspects, the material alteration is defined by an array of separated geometric areas. In one aspect, heat is used during the process of removing the adhesive material from the lead frame. In this aspect, the heat source is a hotplate having a length dimension extending at least the overall length dimension of the lead frame.

In another aspect of the present invention, a method for removing thermal-resist tape from the underside of a lead frame used for chip scale packaging is provided. The method includes the steps of, (a) providing a perforated tab located at least at one end of the lead frame the tab incorporating an edge of the tape by virtue of being adhered thereto, (b) grasping the perforated tab and separating it from the lead frame, the tab remaining adhered to the tape and, (c) peeling the tape away from the surface of the lead frame using the perforated tab as a handle.

In one aspect of the method in step (a), the perforated tab is formed by etching before application of the tape. In another aspect, in step (a), the perforated tab is rectangular. In still another aspect of the above-described method, a step is added between steps (a) and (b) for heating the lead frame to weaken adhesive properties of the tape. In this aspect, the heat source is a hotplate having a length extending to at least the overall length of the lead frame.

Now, for the first time, a tape-removal method that enables simple physical access to the edge of thermal-resist tape applied to a lead frame is provided. Such a method enables easy and secure access to the tape in order to enable safe separation of the tape from the lead frame.

### BRIEF DESCRIPTION OF THE DRAWINGS

FIG. 1 is a broken view of one end of a lead frame according to prior art.

FIG. 2 is a broken view of one end of a lead frame that is modified to allow access to the tape according to an embodiment of the present invention.

FIG. 3 is a broken view of a lead frame that is a modified to allow access to the tape according to an alternate embodiment of the present invention.

### DESCRIPTION OF THE PREFERRED EMBODIMENTS

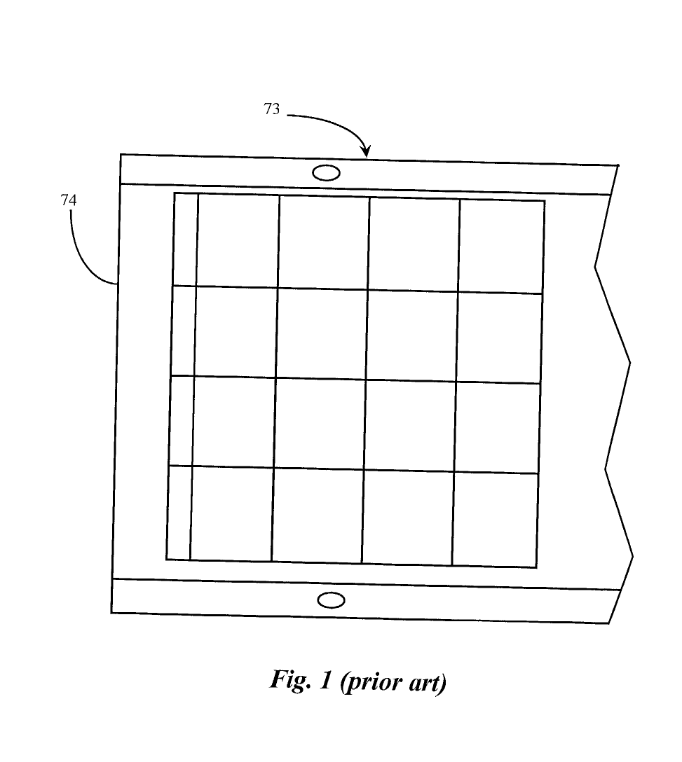

FIG. 1 is a broken view of one end of a lead frame 73 according to prior art. Lead frame 73 represents a typical CSP lead frame according to prior art. In this example, lead frame size is approximately 172×60 mm, however, a lead frame and tape in the art may be any size. In this specification, it is assumed that a high thermal resist tape 74 is present on the underside or side opposite the die-attach pads. In prior-art application, lead frame 73 has tape 74 extending to and cut in alignment with the straight end of the frame. Only one end of lead frame 73 is visible in this example, however tape 74 may be assumed to extend also to the opposite narrow end of frame 73.

As was described in the background section, lead frame 73 is manufactured of a relatively narrow and thin strip of metal sheet. Tape 74 is not removed from lead frame 73 until after molding, but before final curing of encapsulated packages. It is when the tape 74 is removed by hand that lead frame warping or bending, contamination, mold cracking, and other problems can occur.

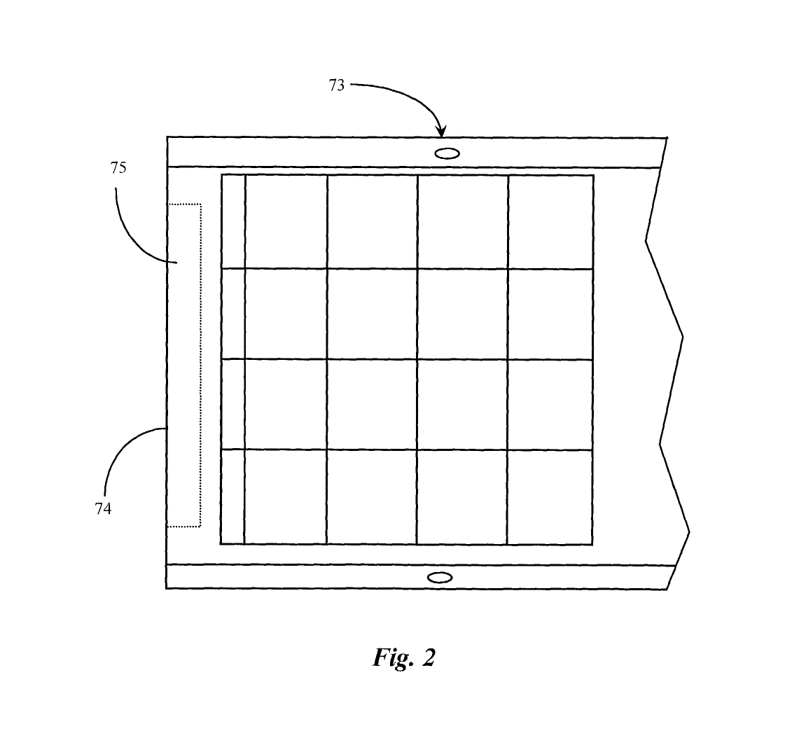

FIG. 2 is a broken view of one end of lead frame 73 modified to allow access to tape 74 according to an embodiment of the present invention. Lead frame 73 is, in this example, modified during manufacturing by providing a breakaway tab 75. Tab 75, illustrated by a dotted boundary, may be formed by etching the boundary to a level of thickness such that it is a simple matter to grasp tab 75 and break it off of lead frame 73. In this example tab 75 is illustrated on the visible end of frame 73. In a preferred embodiment, both ends of frame 73 will have the modification represented by tab 75. It is noted herein that tape 74 is cut along the edges of frame 73 as described in FIG. 1 above. Therefore, it may be assumed that tape 74 covers the entirety of tab 75 to its edge.

To remove the tape 74 from lead frame 73, a user grasps tab 75, thereby also grasping tape 74 and breaks off tab 75 of frame 73 while tape 74 is still attached. Tab 75 becomes, in effect, a tape-handle allowing a broad grasp of tape 74 for efficient tape removal. In one embodiment of the present invention tab 75 and tape 74 are removed at one end of frame 73, the tape peeled off evenly toward the opposite end of frame 73. If frame 73 is equipped with two tabs 75, then both tabs may be removed whereupon the tape is peeled off from both ends toward the center of frame 73. In another embodiment of the present invention, lead frame 73 may be held by vacuum or by mounting and apparatus on to a hotplate adapted for the purpose of heating frame 73 to weaken the adhesive properties of tape 74.

In one aspect of the present invention, tab 75 may extend the entire width of lead frame 73 without departing from the spirit and scope the present invention. Also, the scribed line demarking tab 75 is not limited to a rectangular shape as shown in FIG. 2. The tab may be oval, semi-circular, or other shape as well. The exact dimensions of tab 75 are not specifically important to the present invention except that length and width dimensioning should be sufficient to allow a user to easily grasp tab 75 and to be able to control a substantially large breadth of tape at the tab-end.

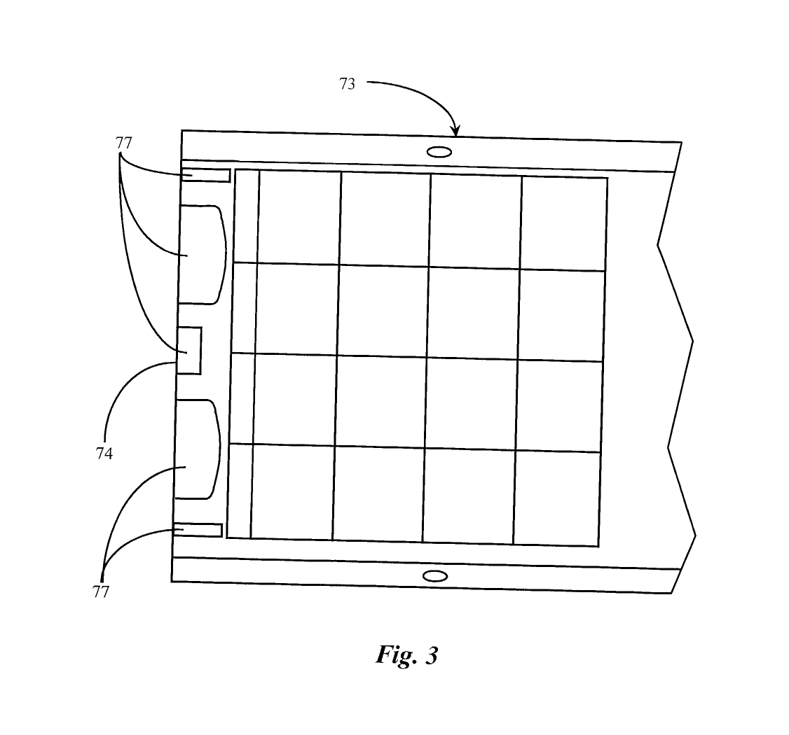

FIG. 3 is a broken view of lead frame 73 modified to allow access to the tape according to an alternative embodiment of the present invention. Lead frame 73 is illustrated in this example as having a plurality of openings 77 provided along the frame-edge. In this example tape 74 may be assumed extend to the straight edge of lead frame 73 as was previously described in FIG. 2 and in FIG. 1. Openings 77 may be provided to a variety of shapes and sizes, as is illustrated in this example. Furthermore, there may be more or fewer openings and differing patterns or combinations of openings provided in frame 73 without departing from the spirit and scope of the present invention. The inventor intends that openings 77 simply represent examples of a variety of openings that may be provided in frame 73 for the purpose of enabling physical access to tape 74. In this embodiment, openings 77 may be assumed to be provided on the opposite end of lead frame 73 as well as the end shown. In this case, tape 74 is accessible by virtue of the fact that there is no lead frame material where there is an opening 77. Tape 74 may be removed in much the same fashion as described in FIG. 2 except that there is no tab still attached to tape 74 while it is being removed.

It will be apparent to one with skill in the art, that tab 75 and openings 77 may be designed into and fabricated along with lead frame 73 during manufacture. In another embodiment, such modifications may be made after IC-packaging houses purchase lead frames. In cases where packaging houses apply the thermal-resist tape to lead frames after purchase, then modifications by tab 75 and/or openings 77 would be provided before tape application to the lead frame.

The present invention may be practiced in any IC packaging environment using lead frames and thermal-resist tape for protecting against resin spill over and the like. Therefore, the method and apparatus the present invention should be afforded the broadest scope possible under examination. The spirit and scope of the present invention is limited only by the claims that follow.

What is claimed is:

1. A lead frame apparatus for holding IC packages during IC package processing comprising:
a substantially flat thin strip of conductive material having substantially parallel sides and square ends forming the lead frame apparatus;
a strip of adhesive material adhered to one surface of lead frame apparatus, the overall dimensions of the strip substantially the same as the overall dimensions of the lead frame apparatus;
a plurality of die-attach pads arranged on the non-adhesive surface of the lead frame apparatus, the pads for receiving IC packages for encapsulation by molding; and
at least one geometric area of material alteration formed in the conductive material forming the lead frame, the area located substantially at either frame end, wherein a user accesses the strip of adhesive material through utilization of the material alteration for the purpose of removing the adhesive material from the surface of the lead frame.

2. The lead frame apparatus of claim 1, wherein the adhesive material is thermal resist tape.

3. The lead frame apparatus of claim 2, wherein the thermal resist tape after application to the frame is dimensionally equal to the overall dimensions of the frame.

4. The lead frame apparatus of claim 3, wherein the material alteration is a perforated tab.

5. The lead frame apparatus of claim 4, wherein the geometric area defining the material alteration is rectangular.

6. The lead frame apparatus of claim 5, wherein the material alteration spans the entire width of the lead frame.

7. The lead frame apparatus of claim 5, wherein etching before application of the adhesive material produces the material alteration.

8. The lead frame apparatus of claim 3, wherein the material alteration is characterized by an absence of material.

9. A lead frame apparatus of claim 8, wherein a material removal process performed before application of the adhesive material produces the material alteration.

10. The lead frame apparatus of claim 9, wherein the geometric area defining the material alteration is rectangular.

11. The lead frame apparatus of claim 9, wherein the geometric area defining the material alteration is annular.

12. The lead frame apparatus of claim 4, wherein the geometric area defining the material alteration is annular.

13. The lead frame apparatus of claim 4, wherein the material alteration is defined by an array of separated geometric areas.

14. The lead frame apparatus of claim 9, wherein the material alteration is defined by an array of separated geometric areas.

15. The lead frame apparatus of claim 1, wherein heat is used during the process of removing the adhesive material from the lead frame.

16. Lead frame apparatus of claim 15, wherein the heat source is a hotplate having a length dimension extending at least the overall length dimension of the lead frame.

17. A method for removing thermal-resist tape from the underside of a lead frame used for chip scale packaging comprising the steps of:
(a) providing a perforated tab located at least at one end of the lead frame the tab incorporating an edge of the tape by virtue of being adhered thereto;
(b) grasping the perforated tab and separating it from the lead frame, the tab remaining adhered to the tape; and
(c) peeling the tape away from the surface of the lead frame using the perforated tab as a handle.

18. The method of claim 17 wherein in step (a), the perforated tab is formed by etching before application of the tape.

19. The method of claim 18 wherein in step (a), the perforated tab is rectangular.

20. The method of claim 19 wherein in a step is added between steps (a) and (b) for heating the lead frame to weaken adhesive properties of the tape.

21. The method of claim 20 wherein the heat source is a hotplate having a length extending to at least the overall length of the lead frame.
